(19) United States
(12) Patent Application Publication
(10) Pub. No.: US 2012/0188687 A1
(43) Pub. Date: Jul. 26, 2012

(54) Dock with USB Port

(75) Inventor: Yasuhiro Yamamoto, Los Angeles, CA (US)

(73) Assignee: EVER WIN INTERNATIONAL CORPORATION, City of Industry, CA (US)

(21) Appl. No.: 13/010,069

(22) Filed: Jan. 20, 2011

(51) Int. Cl. H05K 7/00

(52) U.S. Cl. 361/679.01

(57) ABSTRACT

The dock with USB port is a compact and portable adapter. It has a substantially smaller form factor than the electronic device to be docked with it. The dock with USB port plugs into a USB port and provides an adjustable dock for an electronic device and a pass thru USB port that can be used by another electronic device. The dock with USB port comprises of a housing with a USB plug at one end and a USB port at the other end. A plug that extends from a small flange is provided in a concavity, which angles toward the USB plug, on a side of the housing. An adjustable support is provided adjacent to the concavity to support an electronic device.

### BACKGROUND

1. Field of Invention

The present invention relates generally to electrical adapter plugs. More specifically, the present invention relates to a compact and portable electrical adapter plug with a dock for an electronic device and a universal serial bus port.

2. Description of Related Art

Portable personal electronic devices such as cellular phones commonly have a rechargeable battery that requires periodic recharging when its power is consumed. Many of the portable electronic devices are capable of being recharged by direct currents from a universal serial bus (USB) port such as those commonly found on computers.

The same portable electronic devices can also be recharged with various types of adapters that convert alternating currents, such as those from the common household wall outlets, to direct currents through a USB port. Generally, the electronic device connects to the USB port through a short cable. Once the electronic device is connected to the USB port, the USB port is occupied and no other device can connect to that same USB port.

There are also various recharging docking stations that enable the electronic devices to insert directly into them and recharge their batteries. The docking stations are generally relatively bulky and are designed to remain placed on a stable flat surface such as a desktop and connect to a USB port through a cable. Furthermore, the docks are usually designed specifically to accept a particular electronic device with a specific contour. A different electronic device with even a minor difference in contour or even the same electronic device with a protective case around it will require a different docking station or removal of the protective case for recharging. Furthermore, the docking station that plugs into a USB port usually only accepts one electronic device at a time while occupying the USB port, precluding concurrent use of that USB port by another device.

### BRIEF SUMMARY OF THE INVENTION

The dock with USB port is a compact and portable adapter. It has a substantially smaller form factor than the electronic device to be docked with it. The dock with USB port plugs into a USB port and provides an adjustable dock for an electronic device and a pass thru USB port that can be used by another electronic device. The dock with USB port comprises of a housing with a USB plug at one end and a USB port at the other end. A plug is provided in a concavity, which angles toward the USB plug, on a side of the housing. The plug is extended from a small flange. An adjustable support is provided adjacent to the concavity to support an electronic device.

### BRIEF DESCRIPTION OF THE DRAWINGS

FIG. 1 shows a perspective front view of the dock with USB port.

FIG. 2 shows a perspective rear view of the dock with USB port.

FIG. 3 shows the top side elevation view of the dock with USB port.

FIG. 4 shows the front side elevation view of the dock with USB port.

FIG. 5 shows the bottom side elevation view of the dock with USB port.

FIG. 6 shows left side elevation view of the dock with USB port.

FIG. 7 shows right side elevation view of the dock with USB port.

FIG. 8 shows rear side elevation view of the dock with USB port.

### DETAILED DESCRIPTION OF THE PREFERRED EMBODIMENT

The following description and figures are meant to be illustrative only and not limiting. Other embodiments of this invention will be apparent to those of ordinary skill in the art in view of this description.

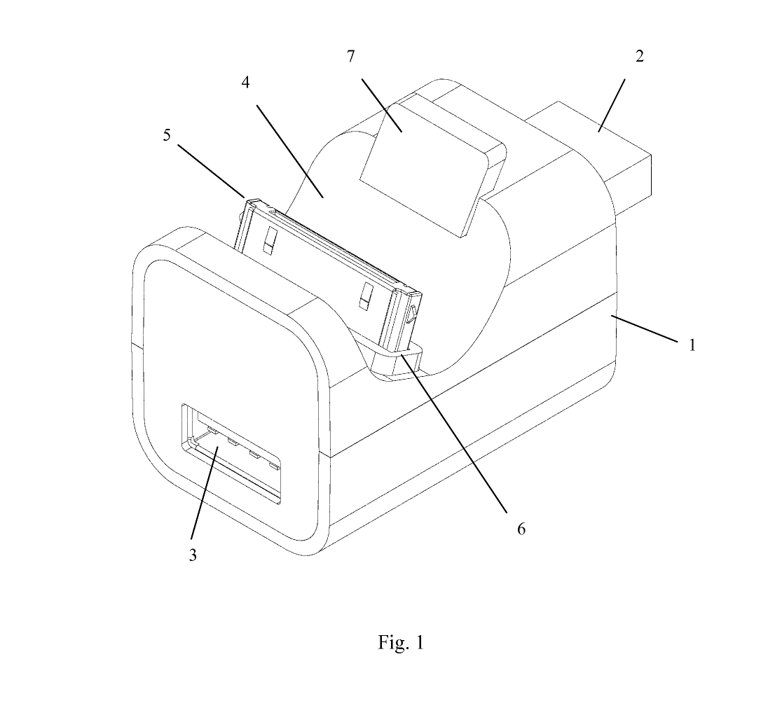

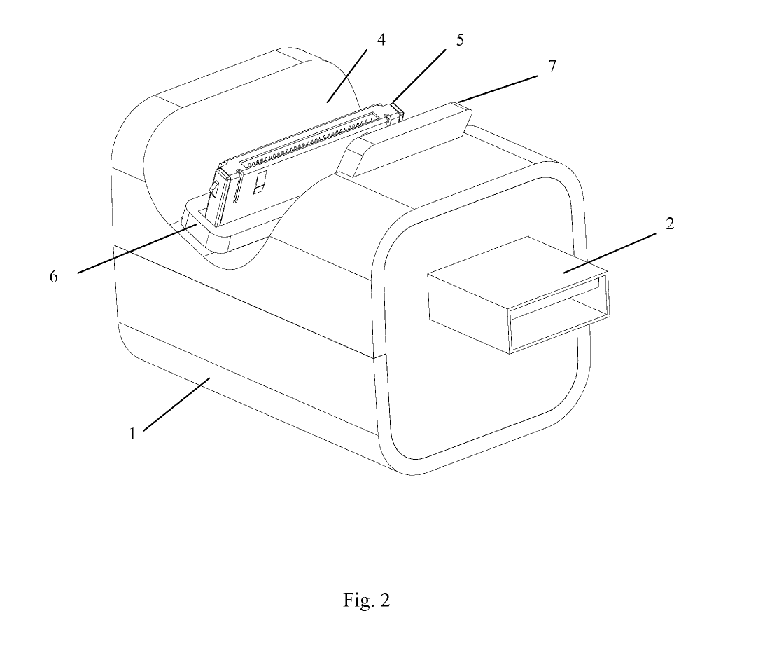

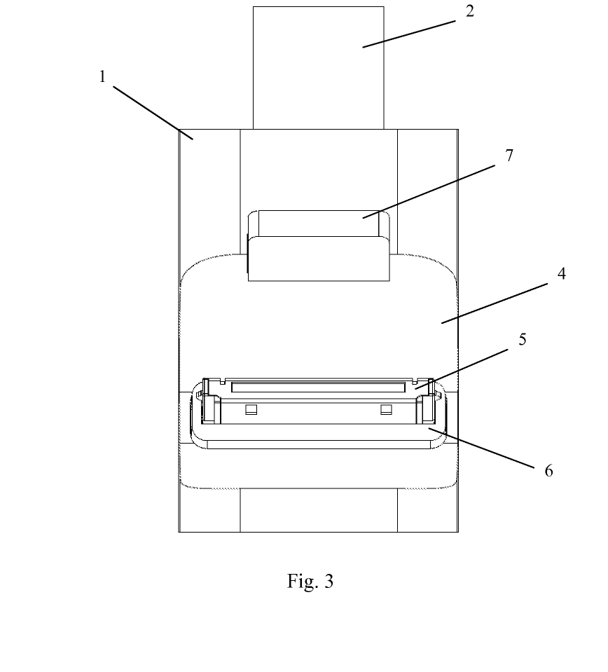

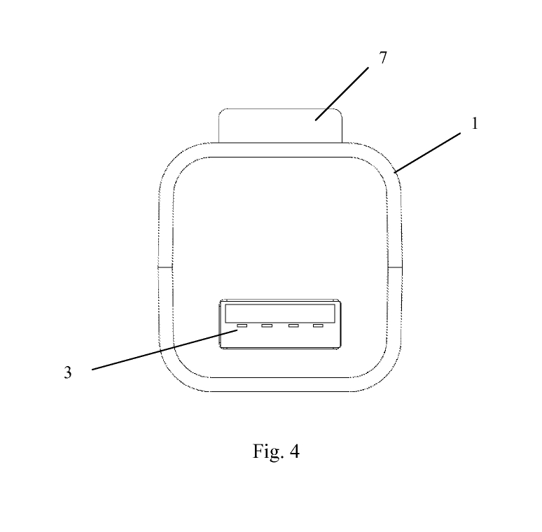

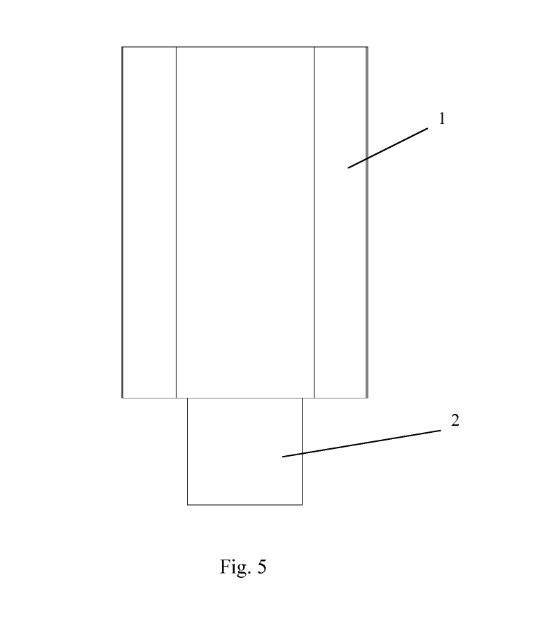

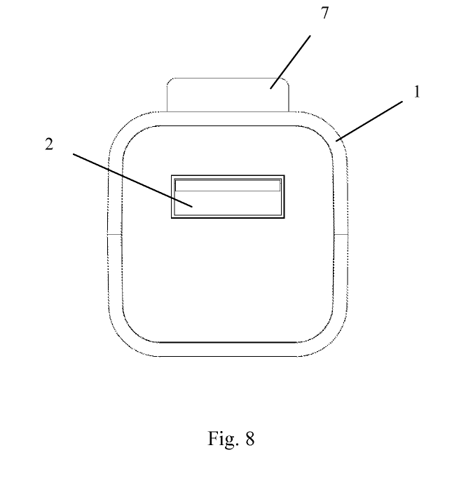

As shown in FIGS. 1 through 8, the dock with USB port is a compact and portable adapter that plugs into a USB port and provides an adjustable dock for an electronic device and a pass thru USB port that can be used by another electronic device. It has a substantially smaller form factor than the electronic device to be docked with it.

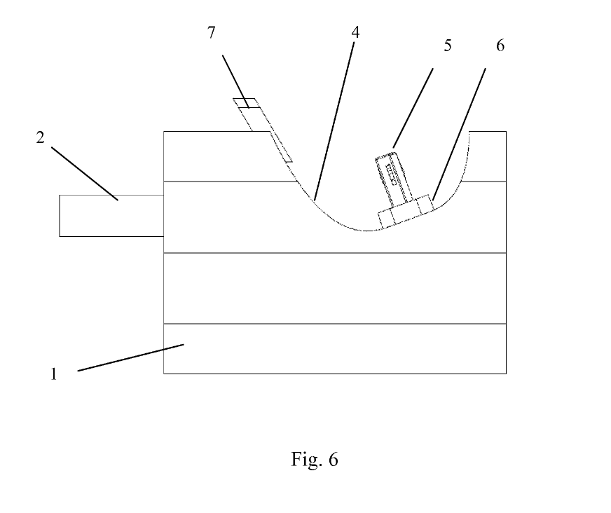

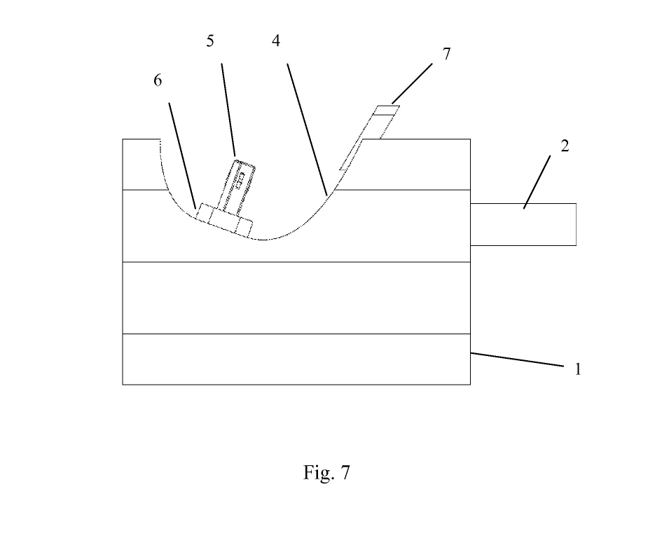

In the preferred embodiment, the dock with USB port comprises of a plastic housing 1 with a USB plug 2 at one end of the housing 1 electrically connected to a USB port 3 at the opposite end of the housing 1. In alternative embodiments, the USB port can be positioned at any side of the housing 1. One side of the dock with USB port has a concavity 4 that angles towards the USB plug 2, as clearly shown in FIGS. 6 and 7. The concavity 4 is adapted to receive a small portion of an electronic device. The angle of the concavity 4 tilts the electronic device towards the USB plug 2, which is usually plugged into a fixed device such as a computer, thereby shifting the center of gravity of the electronic device towards the fixed interface to provide a more stable platform for the electronic device. Additionally, the tilting of the electronic device angles the electronic device away from the USB port 3 on the dock to prevent any possible interference with the use of the pass thru USB port 3. The angle of the concavity 4 further provides a convenient viewing angle and reduce glare of the display screen of the electronic device by tilting the display screen at an angle approximately perpendicular to the viewer's eyes.

A plug 5 that is electrically connected to the USB plug 2 is provided in the concavity 4. In the preferred embodiment, the plug 5 is an Apple proprietary plug adapted to interface with an Apple electronic devices such as iPod, iPhone, and iPad. The plug 5 is extended from a small flange 6. The small flange 6 allows the plug 5 to extend further out from the concavity 4 and enables the plug 5 to be used with an electronic device that is encased in a protective case.

In the preferred embodiment, an adjustable support 7 is provided adjacent to the concavity 4 on the side near the USB plug 2 to support an electronic device. The adjustable support 7 enables a variety of electronic devices to be held stably in the concavity 4 while it is being charged. The adjustable support 7 may be completely removed or retracted for compact storage and transportation.

The dock with USB port provides a convenient and compact adapter for charging a variety of electronic devices and yet does not interfere with the simultaneous use by other electronic devices of the USB port that it is plugged into. It can be adjusted to hold a variety of electronic devices steadily and enables other electronic devices to also use the USB port.

Although the invention has been described in terms of particular embodiments and applications, one of ordinary skill in the art, in light of this teaching, can generate additional embodiments and modifications without departing from the spirit of or exceeding the scope of the claimed invention. Accordingly, it is to be understood that the drawings and descriptions herein are proffered by way of example to facilitate comprehension of the invention and should not be construed to limit the scope thereof.

What is claimed is:

1. A dock with USB port comprising:
a housing with a USB plug at one end electrically connected to a USB port in the housing;
a concavity adapted to receive an electronic device on a side of said housing which angles towards said USB plug; and
a plug that is electrically connected to the USB plug is provided in said concavity.

2. A dock with USB port as in claim 1, wherein said concavity is positioned at an angle that tilts the electronic device towards the USB plug.

3. A dock with USB port as in claim 1, wherein said plug is an Apple proprietary plug adapted to interface with the Apple electronic devices.

4. A dock with USB port as in claim 1, wherein said plug is extended from a small flange.

5. A dock with USB port as in claim 1, wherein an adjustable support is provided adjacent to said concavity.

6. A dock with USB port as in claim 5, wherein said adjustable support is disposed on the side near the USB plug to support the electronic device.

7. A dock with USB port as in claim 5, wherein said adjustable support is removable

8. A dock with USB port as in claim 5, wherein said adjustable support is retractable.

9. A dock with USB port comprising:
a housing with a USB plug at one end electrically connected to a USB port in the housing;
a concavity adapted to receive an electronic device on a side of said housing which angles towards said USB plug wherein an adjustable support is provided adjacent to said concavity; and
a plug that is extended from a small flange and is electrically connected to the USB plug is provided in said concavity.

10. A dock with USB port as in claim 9, wherein said concavity is positioned at an angle that tilts the electronic device towards the USB plug.

11. A dock with USB port as in claim 9, wherein said plug is an Apple proprietary plug adapted to interface with the Apple electronic devices.

12. A dock with USB port as in claim 9, wherein said adjustable support is disposed on the side near the USB plug to support the electronic device.

13. A dock with USB port as in claim 9, wherein said adjustable support is removable

14. A dock with USB port as in claim 9, wherein said adjustable support is retractable.
